(19) United States
(12) Patent Application Publication
(10) Pub. No.: US 2026/0099043 A1
(43) Pub. Date: Apr. 9, 2026

(54) DESIGNING SURFACE OPTICAL ELEMENTS OF WAVEGUDIES

(71) Applicant: Sony Group Corporation, Tokyo (JP)

(72) Inventors: Zhao Wen Chow, Tokyo (JP); Sébastien De Cunsel, Kanagawa (JP); Lorenzo Servadei, Munich (DE); Kazue Shimizu, Kanagawa (JP)

(73) Assignee: Sony Group Corporation, Tokyo (JP)

(21) Appl. No.: 19/354,126

(22) Filed: Oct. 9, 2025

Related U.S. Application Data
(60) Provisional application No. 63/705,301, filed on Oct. 9, 2024.

(51) Int. Cl. G02B 27/00; G02B 27/01; G06F 30/27

(52) U.S. Cl. CPC G02B 27/0012; G06F 30/27; G02B 27/0172; G02B 2027/0178

(57) ABSTRACT

A device includes at least one processor and memory including instructions, that when executed by the at least one processor, cause the processor to select a waveguide design from among a plurality of waveguide designs, the selected waveguide design comprising at least one region having photonic structures, and evaluate the at least one region of the selected waveguide design using a neural network, the neural network using one or more structural parameters of the at least one region as input to generate output that comprises at least one prediction for the selected waveguide design.

### CROSS REFERENCE TO RELATED APPLICATIONS

This application claims priority to and the benefit of U.S. provisional application number 63/705,301, filed on Oct. 9, 2024, the entire contents of which are hereby incorporated by reference.

### FIELD

Example embodiments relate to design and layout creation for surface optical elements of a waveguide, for example, in waveguide-based displays.

### BACKGROUND

Waveguide-based displays may be used for near-eye display devices such as head mounted display (HMD) devices in augmented reality (AR) and/or mixed reality (MR) applications. For HMD applications and other applications, a waveguide may include surface optical elements (e.g., microstructures or nanostructures) whose design affects how light is input to, propagated within, and output from the waveguide.

### SUMMARY

An illustrative embodiment is directed to a device, comprising: at least one processor; and memory including instructions, that when executed by the at least one processor, cause the processor to: select a waveguide design from among a plurality of waveguide designs, the selected waveguide design comprising at least one region having photonic structures; and evaluate the at least one region of the selected waveguide design using a neural network, the neural network using one or more structural parameters of the at least one region as input to generate output that comprises at least one prediction for the selected waveguide design.

Another illustrative embodiment is directed to a system, comprising: at least one machine learning algorithm; at least one processor; and memory including instructions, that when executed by the at least one processor, cause the processor to: select a waveguide design from among a plurality of waveguide designs, the selected waveguide design comprising at least one region having photonic structures; and evaluate the at least one region of the selected waveguide design based on output of the neural network, the at least one machine learning algorithm using one or more structural parameters of the at least one region as input to generate output that comprises at least one prediction for the selected waveguide design.

Yet another illustrative embodiment is directed to a method, comprising: selecting a waveguide design from among a plurality of waveguide designs, the selected waveguide design comprising at least one region having photonic structures; and evaluating the at least one region of the selected waveguide design using a graphical neural network, the neural graphical network using one or more structural parameters of the at least one region as input to generate output that comprises at least one prediction for the selected waveguide design.

### BRIEF DESCRIPTION OF THE FIGURES

FIG. 1 is a block diagram of a system according to at least one example embodiment.

FIG. 2 illustrates a schematic view of a display device and an example of a k-space design diagram for the display device according to at least one example embodiment.

FIG. 3 illustrates a system for selecting and evaluating waveguide designs according to at least one example embodiment.

FIG. 4 illustrates a method for arriving at a final waveguide design according to at least one example embodiment.

FIG. 5A illustrates example structural parameters of a waveguide and FIG. 5B illustrates an example of how such structural parameters may be mapped to a NN according to at least one example embodiment for the purposes of evaluation.

FIG. 6 illustrates a method for arriving at a final waveguide design according to at least one example embodiment.

FIG. 7 illustrates a schematic view of a head mounted display (HMD) according to at least one example embodiment.

### DETAILED DESCRIPTION

Photonic waveguides are promising optical building blocks for several applications, including for the development of Augmented Reality (AR)/Mixed Reality (MR) displays. In AR and MR displays, photonic waveguides employ surface relief gratings (SRGs) with multiple diffractive optical elements (referred to herein as photonic structures, microstructures, metasurface(s), nanostructures, and the like) to replicate an image generated by optical engine (light source) and display the image to a user's eyes. Photonic waveguides for display applications have three main functionalities: input pupil coupling, pupil replication (or expansion), and output pupil coupling, some or all of which may include SRGs with photonic structures (also called diffractive optical elements). Photonic waveguide display principles may also be applied to other optical technologies, such as image sensing and data transfer. For example, image sensors may comprise photonic structures to guide/refract light to photosensitive regions (e.g., photodiodes) of the sensor.

Regardless of field, properties (e.g., size, shape, material, etc.) of photonic structures within a single optical device change may change according to application (e.g., image display vs. image sensing vs. data transfer) and design constraints. For example, gratings for AR/MR displays may include groups of photonic structures arranged in unit cell or segments. As another example, a photonic structures for image sensing may include microstructures and/or nanostructures designed to diffract specific wavelengths of light. This variety of applications and design constraints leads to a large number of design possibilities for an SRG. Stated another way, the number of variables available to optical designers to create SRGs is extremely dense and finding the optimal combination is technically challenging and time/resource intensive. The complexity of this combinatorial problem becomes large and requires an unreasonably long time to solve using related art optimizers. Inventive concepts are aimed at tackling this complexity by leveraging design knowledge and artificial intelligence processes within a fully integrated optical design flow that connects the optical design process with the customer requirements to deliver the best optical display/hardware possible within the provided constraints.

As described in more detail herein, resource efficient methods for arriving at an optimal or near-optimal waveguide design may comprise using structural parameters of a proposed waveguide design selected from among a number of possible waveguide designs as an input to obtain one or more performance parameters for the waveguide design under analysis which may be physical, optical, and/or abstract properties of the waveguide design. Structural parameters that correspond to physical properties of a waveguide design include unit cell and/or photonic structure, shape, size, layout (e.g., contour of unit cells or segments). Structural parameters that correspond to optical properties of a waveguide design include waveguide material, which may vary according to whether the waveguide is used for display, sensing, data transfer, or other purpose. Structural parameters that correspond to abstract properties of a waveguide design may include properties of a waveguide which are correlated with performance and/or derived from one of the physical and/or optical properties. As may be appreciated, the output of the methods described herein comprises information about performance parameters of the evaluated waveguide design, which may include layout information, optical performance of the full waveguide, image quality, efficiency, and/or the like.

In some examples, the method may use a machine learning algorithm (e.g., a neural network (NN), such as a graphical neural network), with the inputs of the NN defined by at least one physical, optical and/or abstract property of the waveguide and/or its components and the outputs of the NN being partial or complete predictions of at least one physical, optical and/or abstract properties of the waveguide.

Inventive concepts propose an optimization strategy for finding the optimal design of an SRG, regardless of application (display, image sensing, data transfer, etc.). Given a design space (i.e., a proposed SRG with photonic structures), the AI-based optimization may: 1) select/sample one or multiple design(s) to evaluate; 2) estimate ray tracing (RT) outputs for selected design using a neural network (NN) (a neural network may be leveraged to learn RT patterns given the design space which reduces the need to run a complete RT algorithm in every iteration); 3) perform a RT algorithm if required; 4), compute/extract/convert predicted the performance of the SRG given the available data; 5) evaluate the selected/sampled design(s) based on the predicted performance from 4); and 6) return the selected design(s) for fabrication if the predicted performance is sufficient, else return to step 1) and repeat steps 1) to 6). As may be appreciated the time needed to find the optimal or desired SRG design is therefore reduced and faster development cycles becomes possible.

Stated in other terms, at least one aspect of the present disclosure is directed to a procedure for designing a waveguide comprising of a plurality of unit cells arranged in groups on the base substrate(s). The procedure may comprise 1) a wave-based analytical or semi-analytical method in computational electromagnetics (e.g. FDTD, RCWA) and/or a dataset generated using a similar software/program, 2) a wave/ray-tracing based software/algorithm computing the wave/ray propagation/path guided within the light plate, and 3) sampling software/algorithm in charge of selecting the design candidates to be partially or fully evaluated by the previous 2 processes. An AI-based software/algorithm may be directly connected to one or more of the three previously listed processes and/or independently used within the design procedure. The design procedure may be used for a waveguide-based display, where the total number of different unit cells equals or exceeds 15, and where the various unit cells can be arranged within an input coupling region (IC), an expansion coupling region (EC) and/or an output coupling region (OC). The output of the procedure may comprise physical, optical and/or abstract properties of the waveguide. Deep-learning (DL) methods, in particular neural networks (NN) with three or more layers, including the input and output layers, that have learnable weights. The inputs of the NN are defined by a minimum of one physical, optical and/or abstract property of the waveguide and/or its components, and the outputs are partial or complete predictions of the physical, optical and/or abstract properties of the waveguide. In some examples, the NN is a Graphical Neural Network (GNN), where the input layer has in a graph representation, and where a new/updated graph representation is the output layer. The input to output mapping is made of one or more message passing layer(s), where the passings layer updates the graphs properties using some or all available features or structural parameters of a waveguide. Each graph representation may be made of one or more vertices, zero or more edges. Each vertex and edge is defined by at least one physical, optical and/or abstract property of unit cells group and/or other components of the waveguide and/or itself. Each graph may also comprise of a global representation (also called master node) defining one or more common physical, optical and/or abstract properties of unit cells and/or other components of the waveguide and/or itself, shared by all its vertices and edges. The AI-based software/algorithms are used as a potential replacement of the three main steps of the software solution listed above as 1) to 3). In some cases, one or multiple decision-making algorithms decide to either use the AI-based software/algorithm to evaluate the output of one or more main steps, or use of the main steps themselves. The AI-based software/algorithms may be used sequentially and/or in parallel, and an AI-based software/algorithm may directly interfere with another AI-based software/algorithm.

Example embodiments will now be described with reference to the figures, which generally relate to systems and methods for designing SRGs for waveguide-based displays.

However, it should be appreciated that the systems and methods described herein may be applied to optical gratings within other applications, such as image sensing, data transfer, or other suitable application which uses optical gratings.

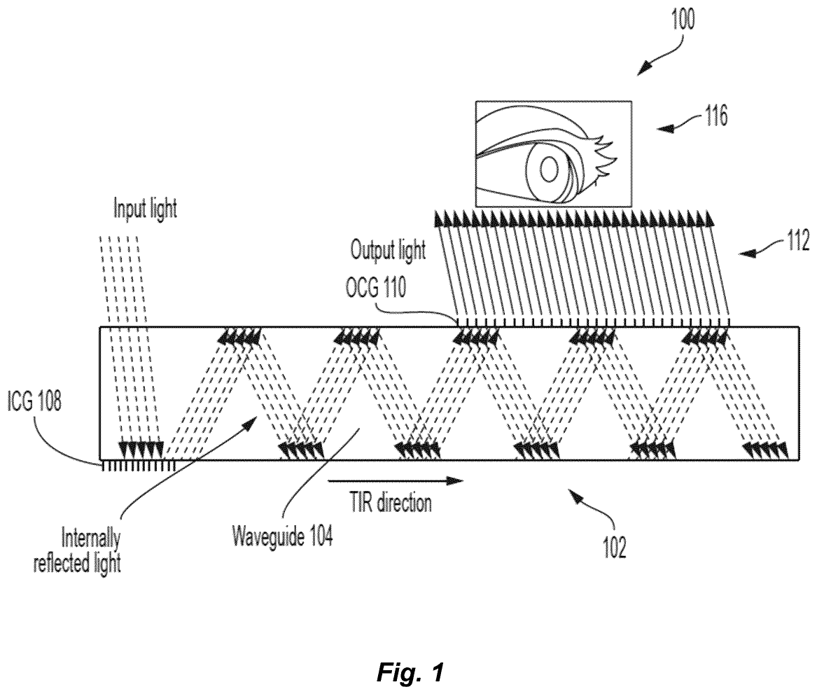

FIG. 1 is a block diagram of a system 100 including a display device 102 according to at least one example embodiment. The display device 102 may be a waveguide-based display and include a waveguide 104, an input coupling grating (ICG) 108, an output coupling grating (OCG) 110, and an eyebox 112 that outputs light to a user 116.

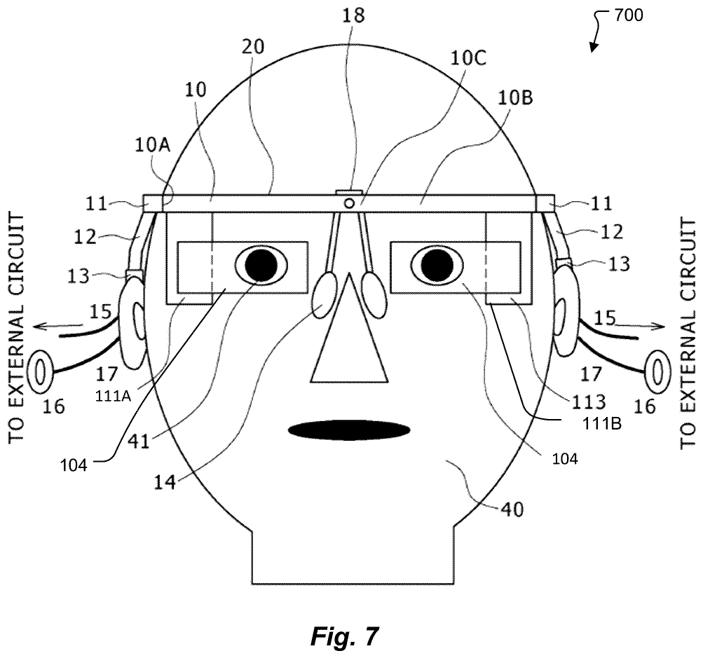

The waveguide 104 receives input light incident on a first surface of the waveguide 104 from a light source or an image generating device (not shown, but see FIG. 7 for additional detail of an image generating device). The received light is received by an input region of the ICG 108 on a first surface of the waveguide 104 and redirected (e.g., diffracted) at a propagation angle for internal reflection (e.g., total internal reflection (TIR)) within the waveguide 104. The internally reflected light may travel within the waveguide 104 before encountering OCG 110 at a second surface of the waveguide 104. The waveguide 104 may be fixed to or on a substrate or base (not illustrated). The OCG 110 has a structure that diffracts at least some of the internally reflected light to an eyebox 112 of the display device 102 as output light for viewing by the user 116. An area of the waveguide 104 located between the ICG 108 and OCG 110 may correspond to an expansion area. The input light may be generated by the light source under control of image processing circuitry (not shown) or an image generating device that controls the light source to output light in a manner that displays a still image and/or moving images to the user 116 through the eyebox 112, thereby providing an AR image or MR image to the user 116. The eyebox 112 may include an area or volume in which a user's eye will receive a view of the output light. The light source may comprise any suitable light source used for diffractive waveguide applications, for example, one or more light emitting diodes (LEDs) or other light source coupled with one or more lenses and/or prisms that direct light to the waveguide 104.

The waveguide 104 may comprise any suitable material for diffractive waveguide applications, for example, glass, plastic, polymer, or other suitable organic or inorganic optical material. The waveguide 104 may be implemented in any suitable manner. For example, the waveguide 104 may comprise a core and one or more cladding layers, where the core and the cladding layer(s) have different dielectric constants. In another example, the waveguide 104 may be implemented with silicon photonics.

As described herein, the ICG 108, the expansion area, and/or OCG 110 may comprise photonic structures (e.g., protrusions and/or indentations—also called metasurface structures, nanostructures, or microstructures) at one or more surfaces of the waveguide 104. The photonic structures of each region may be formed according to suitable nanoimprint lithography methods and/or ink-jet methods. The photonic structures may be formed on the surface(s) of the waveguide 104 (i.e., the photonic structures are not part of the waveguide 104, but instead placed on the surface(s) of waveguide 104) and/or included as part of the surface(s) of the waveguide 104. The photonic structures may take a suitable shape or form. For example, the photonic structures may comprise one-dimensional structures (e.g., linear structures), two-dimensional structure (pillars, holes, and/or the like), metasurfaces, and/or other suitable form. In any event, the specific design of the photonic structures of a waveguide 104 may be based on the optical characteristics desired for the output light of the display device 102. As described in more detail below, the waveguide 104 may include photonic structures 300 arranged into segments with each segment comprising a number unit of cells designed to improve diffraction coupling efficiency and/or specular reflection coupling efficiency. Each unit cell may comprise a number of photonic structures having the same structure or properties (size, shape, material), with the properties of photonic structures varying across the unit cells of a particular segment.

The eyebox 112 may correspond to a volume of free space where the eye of the user 116 receives a view of an image created by the light output from the OCG 110. The size and location of this volume may be based on optical architecture choices in which designers trade-off a number of constraints, such as field of view (FOV), image quality, and product design.

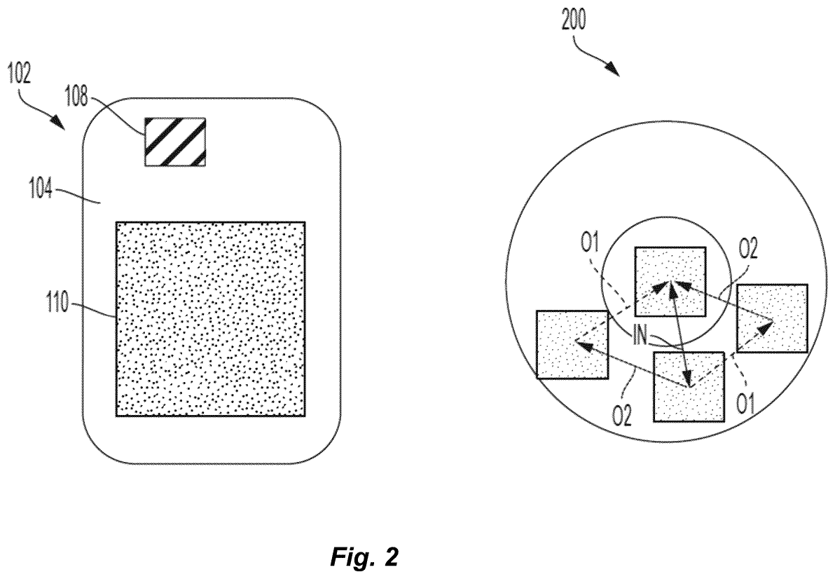

FIG. 2 illustrates a schematic view of a display device 102 and an example of a k-space design diagram for the display device 102 according to at least one example embodiment. As may be appreciated from the k-space design diagram 200, IN is the in-coupling vector for ICG 108, while O1 and O2 are the expansion and outcoupling unit vectors, respectively, for the expansion area of the waveguide and the OCG 110.

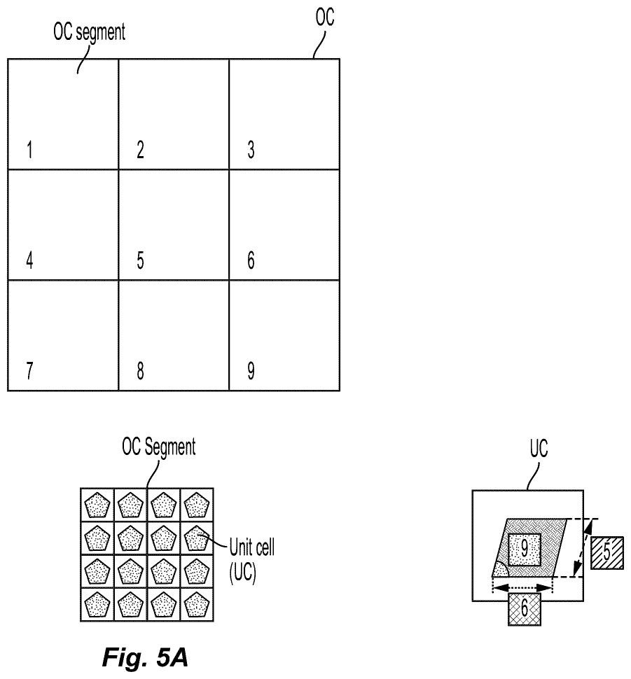

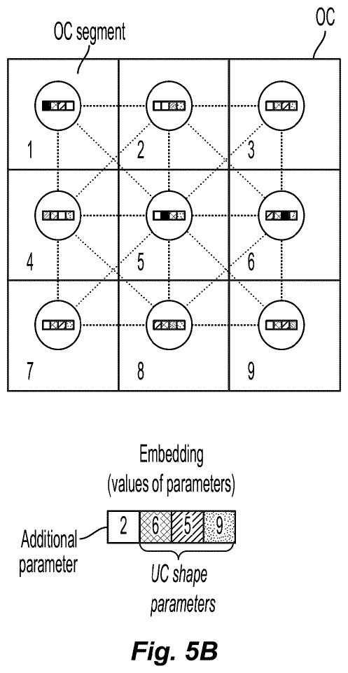

As described herein, a waveguide 104 may be divided into segments with each segment having a number of unit cells and with each unit cell containing photonic structures being arranged a pitch within the unit cell, such as at a substantially same pitch (the term “substantially” is used herein to account for variations that may occur as a result of the manufacturing process). FIGS. 5A and 5B illustrate a non-limiting example of this arrangement and are described in more detail below. Each unit cell within a segment may have a set photonic structures that have substantially the same characteristics (e.g., size, shape, and/or material) within that unit cell, and the characteristics of the photonic structures may differ for each unit cell within a segment as well as across the segments of the waveguide. For example, the photonic structures across unit cells may differ according one or more possible mutations in the y, z axis (additions, subtractions, and/or rotations) of a rectangular reference shape according to at least one example embodiment. Other suitable reference shapes include a triangular shape, a square shape, a rhombus shape, a trapezoid shape, an irregular polygon shape, a regular polygon shape and/or the like. In general for waveguide-based displays, the photonic structures may have a critical dimension sized between 5 nm and 1000 nm or between 20 nm and 600 nm, and a total number of mutation changes between unit cells sharing a border may be limited to three. In addition, the number of segments of the waveguide 104 may range from in the tens to hundreds (e.g., 15 to 200) with the number of unit cells in each segment varying according to design but generally exceeding 10. As may be appreciated from the above discussion, there are thousands possibilities for designing a particular waveguide, and thus, example embodiments propose systems and methods to aid with selection of a particular design.

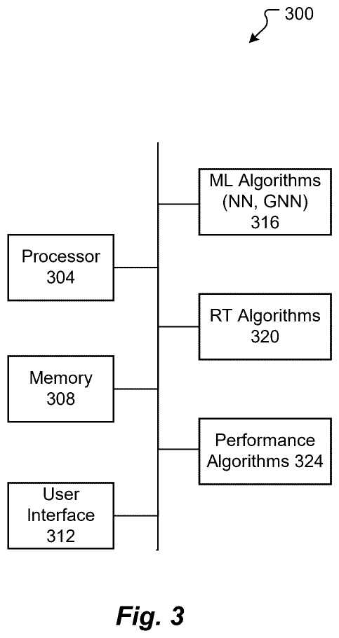

FIG. 3 illustrates a system 300 for selecting and evaluating waveguide designs according to at least one example embodiment.

The system 300 includes a processor 304, memory 308, user interface 312, machine learning (ML) algorithms 316, ray tracing (RT) algorithms 320, and performance algorithms 324. The system 300 may perform one or more of the methods described herein.

The processor 304 may include one or more circuits for carrying out computing tasks to perform the waveguide selection and evaluation methods described herein. In addition, the processor 304 may execute one or more of the algorithms depicted in FIG. 3 or be in communication with one or more other processors executing those algorithms. The processor 304 may include an Integrated Circuit (IC) chip, a Central Processing Unit (CPU), a Graphics Processing Unit (GPU), a microprocessor, a Field Programmable Gate Array (FPGA), a digital signal processor (DSP), an application specific integrated circuit (ASIC), a collection of logic gates or transistors, resistors, capacitors, inductors, diodes, or the like. Some or all of the processor 304 may be provided on a Printed Circuit Board (PCB) or collection of PCBs. It should be appreciated that any appropriate type of electrical component or collection of electrical components may be suitable for inclusion in the processor 304.

The memory 308 may correspond to any suitable type of memory device or collection of memory devices configured to store data, such as instructions to be executed by the processor 304. Non-limiting examples of suitable memory devices that may be used include flash memory, Random Access Memory (RAM), Read Only Memory (ROM), variants thereof, combinations thereof, or the like. In some embodiments, the memory 308 and processor 304 may be integrated into a common device (e.g., a microprocessor may include integrated memory).

The user interface 312 may comprise one or more user input devices and one or more user output devices. User input devices may include, a mouse, keyboard, a touch display, and/or any other suitable device that enables a user to interact with other elements of the system 300. User output devices may include one or more displays that enable a user to view information about the system 300, speakers for emitting sound, and/or any other suitable device that enables a user to understand interaction with other elements of the system 300.

The ML algorithms 316 may include any suitable algorithm for making predictions within the context of the steps for designing a waveguide described with reference to the figures described below, for example. An ML algorithm may correspond to a model trained with data to make such predictions. Specific examples of ML algorithms applicable to the present disclosure are a neural network (NN), and specifically, a graphical neural network (GNN). However, any suitable ML algorithm may be used. Ray tracing (RT) algorithms 320 may include any suitable and commercially available (e.g., open source or for-purchase) or non-commercially available software for simulating or modeling light transport within a waveguide. In some examples, a finite-difference-time-domain (FDTD) algorithm, a rigorous-coupled-wave-analysis (RCWA), or other suitable algorithm for solving Maxwell's equations may be implemented to compute and store (e.g., in a look-up table or other database format) physical, optical, and/or abstract properties for a particular waveguide design, which a RT algorithm 320 may access to perform ray tracing for that particular waveguide design. Stated another way, the ray-tracing algorithm may use RCWA-computed (or FDTD-computed) properties (e.g., stored in look-up tables) of each photonic region/structures as inputs and computes the RT outputs obtained by combining those structures (position, layout, etc.).

Performance algorithms 324 may include any suitable and commercially available (e.g., open source or for-purchase) or non-commercially available software for simulating or predicting performance of a waveguide.

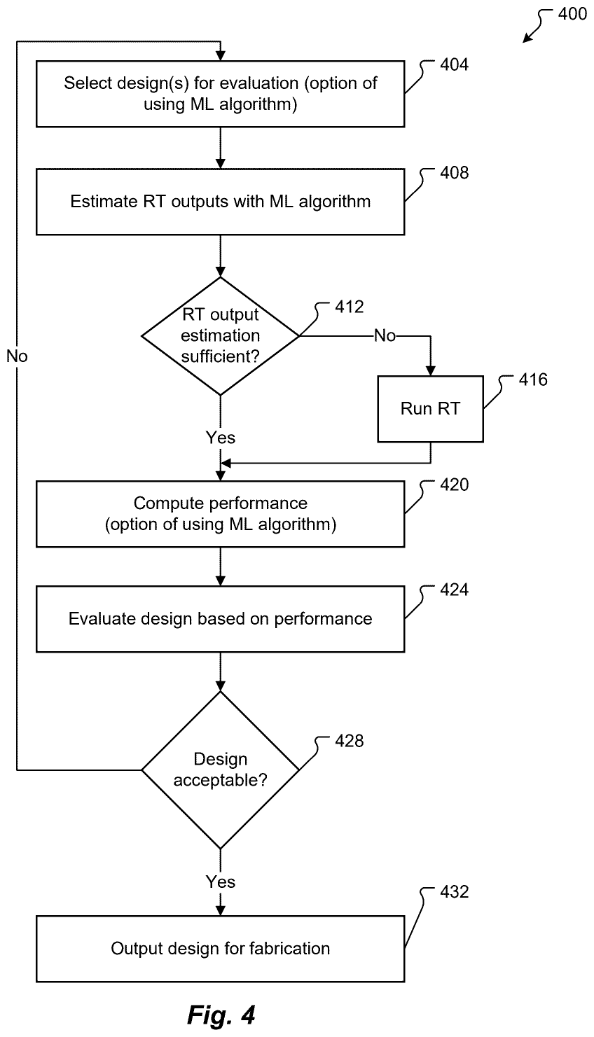

FIG. 4 illustrates a method 400 for arriving at a final waveguide design according to at least one example embodiment. The method 400 may be performed by one or more elements of the system 300 in FIG. 3, such as the processor 304 executing algorithms 316, 320, and/or 324 and/or the processor 304 being in communication with other devices executing the algorithms 316, 320, and/or 324.

Step 404 includes selecting one or more waveguide designs for evaluation with the method 400. The selected waveguide design(s) may be selected from a larger set of possible waveguide designs which may number in the thousands. For example, step 404 may select 10-20 designs for evaluation from a larger set of 1,000-2,000 possible designs. Step 404 may include randomly selecting waveguide designs for evaluation from the larger subset. In some examples, the waveguide designs are selected using a sampling algorithm that uses historical data from previous iterations of the method 400 with the goal of converging to the “best” design(s) with a minimal number of iterations of the method 400. In some examples, the waveguide design(s) are selected based on output of an ML algorithm 316 which has been trained with structural and performance data from historical waveguide designs. In other examples, the waveguide design(s) selected in step 404 are based on user input to user interface 312.

In step 408, the method 400 estimates ray tracing (RT) outputs for the selected waveguide design(s), for example, with an ML algorithm such as a neural network, more specifically a graphical neural network GNN which has nodes connected to neighboring nodes. The GNN may have at least three layers of nodes, an input set of nodes, one or more intermediate sets of nodes, and an output set of nodes that provide a prediction for RT outputs. FIGS. 5A and 5B illustrate one example of using a GNN to estimate RT outputs for a particular region of a waveguide (e.g., an OCG region of a waveguide for MR/AR devices). Estimating RT outputs according to step 408 may significantly reduce the amount of time and computing resources normally used to run a full ray tracing simulation to arrive at the same/similar result as the estimation, thus, conserving computing resources and reducing the amount of time to arrive at a final waveguide design.

Step 412 determines whether the RT outputs from step 408 are sufficient for use in step 420 to compute performance parameters of the selected waveguide design. If so, the method proceeds to step 420 to compute the performance parameters, and if not, the method proceeds to step 416 where a complete ray tracing is performed for the selected waveguide design with the RT algorithms 420. Step 412 may include determining whether RT output estimation in step 408 was deficient in some respect, such as failing to meet one or more expectations that would be met if the selected waveguide design was run through a complete ray tracing algorithm. For example, if one or more minimum performance values are not met or are met but not precise enough to proceed to step 420, the method proceeds to step 416.

Step 420 includes computing predicted performance of the selected waveguide design based on the ray tracing outputs from the ML algorithm in step 408 or the RT algorithm in step 416. Step 420 may include computing one or more predicted performance parameters for each region (e.g., segment of group of segments) of the selected waveguide design and then combine the predicted performance parameters for all regions of the waveguide to rank or rate the performance of the selected waveguide design using the algorithms 324. In waveguide-based display applications, the predicted performance parameters may comprise image quality, optical efficiency, field of view uniformity, color uniformity, resolution, eyebox uniformity (e.g., efficiency values for various eye positions within the eyebox), one or more other types of uniformity evaluation metrics, or any combination thereof. However, example embodiments are not limited thereto and the predicted performance parameters may vary according to the application in which the selected waveguide design is implemented. For example, a waveguide in image sensor applications may have predicted performance parameters related to quality of a sensed image, such as resolution and color accuracy, or qualities of a pixel signal used to generate the sensed image, such as signal-to-noise ratio (SNR), conversion gain, and/or signal power.

Step 424 includes evaluating the waveguide design based on the predicted performance parameters. For example, step 424 includes comparing the predicted performance parameters of the selected waveguide design from step 420 to desired or expected performance parameters associated with the implementation of the selected waveguide design. The comparison may include comparing each predicted performance parameter with a corresponding desired performance parameter to determine whether the predicted performance parameter is within an acceptable tolerance of the desired performance parameter. In some examples, step 424 includes implementing a ranking/classification system that combines performance parameters of all regions of the selected waveguide to optimize a single-objective loss function (e.g., by minimizing the objective loss function). In any event, the results of step 424 may be displayed or otherwise indicated to a user on the user interface 312 along with a prompt for the user to accept or reject the selected waveguide design as the final waveguide design in step 428.

Acceptance or rejection of the selected waveguide design as the final waveguide design in step 428 may depend on whether a threshold number of predicted performance parameters were determined to meet the desired performance parameters in step 424. The threshold number of predicted performance parameters may vary according to the application for the selected waveguide design (e.g., display, image sensing, data transfer). In addition, each performance parameter may have an adjustable weight (adjustable via the user interface 312) so that some parameters are weighted more heavily than others in the determination of step 428.

If the selected waveguide design is determined to be acceptable in step 428, for example, because the selected waveguide design met the threshold number of predicted performance parameters, then the method proceeds to step 432 and outputs the final waveguide design for fabrication. Step 432 may include sending the final waveguide design to a system that fabricates (e.g., prints or stamps) a waveguide in accordance with the structural parameters of the final waveguide design, which may include number, size, and shape of segments on the waveguide, number, size, and shape of unit cells within each segment, and number, size, shape, and pitch of photonic structures within each unit cell. Although not shown, the final waveguide design may then be fabricated for use in the desired application (e.g., image display, image sensing, data transfer). If the selected waveguide design is not acceptable in step 428, for example, because the selected waveguide design did not meet the threshold number of predicted performance parameters, then the method 400 returns to step 404 to run another iteration.

Here, it should be appreciated that an iteration of the method 400 may be performed in parallel for multiple selected waveguide designs. Alternatively, the method 400 iterates in a serial fashion for a group of selected waveguide designs.

FIG. 5A illustrates example structural parameters of a waveguide and FIG. 5B illustrates an example of how such structural parameters may be mapped to a NN according to at least one example embodiment for the purposes of evaluation by the method 400 and/or the method 600 described below. It should be appreciated, FIGS. 5A and 5B illustrate a nonlimiting example for mapping an output structural parameters of an coupling (OC) region (also called an OCG herein) to a GNN, and that the same or similar concepts may be applied to any region of a waveguide being evaluated by methods 400 and/or 600 described herein. In addition, one may map the structural parameters of a region of a waveguide to the GNN or another ML algorithm in other suitable manners.

FIG. 5A illustrates an OC region (labeled OC) with nine segments 1-9. Each segment may comprise a plurality of unit cells UC, and FIG. 5A illustrates an example where each segment 1-9 includes sixteen unit cells UC having pentagon shape (notably, FIG. 5A is a simplified example—in reality, the number of unit cells within a segment may exceed 100,000 and reach tens or hundreds of millions depending on segment size). Although not explicitly shown, each unit cell UC may include a plurality of photonic structures arranged at a particular pitch and having a same size and shape across the unit cell. As shown in FIG. 5A, a unit cell UC may be defined by one or more structural parameters labeled as 5, 6, and 9. These structural parameters may describe or include information about the size /d/ shape of the UC and/or the material of, the size of, the shape of, the number of, and/or pitch of the photonic structures in the UC.

As shown in FIG. 5B, a GNN may be constructed such that the OC region is mapped to a layer of the GNN. For example, the structural parameters of the UC from FIG. 5A are mapped to the OC region by considering each segment in the OC region as a node of the GNN embedded with information corresponding to the structural parameters from FIG. 5A and/or other parameters of the UC considered useful for evaluating a selected waveguide design. As illustrated with the edges in FIG. 5B, neighboring nodes of the GNN embedded with their information are connected to immediately neighboring nodes in the x, y directions and diagonally.

As alluded to above, FIG. 5B illustrates one (simplified) example of a GNN configuration used to generate an AI model to estimate RT outputs from step 408 without performing a full wave/ray tracing simulation (i.e., without performing the RT algorithm in step 416). However, it should be appreciated that the structural parameters, node definitions, edge definitions, and the like may be changed to create other implementations of the GNN. The benefits of using a GNN (over a NN or other ML algorithm) are related to how the problem being solved lends itself to being represented by graph structures - there are direct dependencies between neighboring segments (represented in the GNN as nodes) of the waveguide (represented in the GNN by the edges between the nodes). Thus, using a GNN may converge to a final waveguide design faster than other ML algorithms.

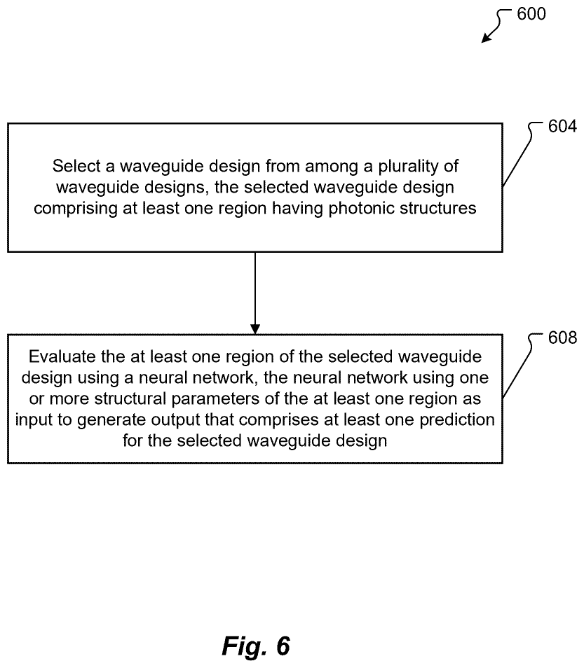

FIG. 6 illustrates a method 600 for arriving at a final waveguide design according to at least one example embodiment. The method 600 may be performed by one or more elements of the system 300 in FIG. 3, such as the processor 304 executing algorithms 316, 320, and/or 324 and/or the processor 304 being in communication with other devices executing the algorithms 316, 320, and/or 324. The method 600 may be related to the method 400 in that with one or steps from method 600 may overlap with step(s) from method 400 but are described in different terms.

Step 604 includes selecting a waveguide design from among a plurality of waveguide designs, the selected waveguide design comprising at least one region having photonic structures. Step 604 may be performed in accordance with step 404 in FIG. 4. For example, step 604 may be performed based on output of a sampling algorithm applied to the plurality of waveguide designs. In some examples, step 604 is based on output of a machine learning algorithm trained with historical data from past iterations of step 604 and/or other useful data. The at least one region may comprise a plurality of segments, each segment comprising a plurality of unit cells having the photonic structures (see FIGS. 5A and 5B, for example).

Step 608 may include evaluating the at least one region of the selected waveguide design using a neural network. The neural network using one or more structural parameters of the at least one region as input to generate output that comprises at least one prediction for the selected waveguide design. The one or more structural parameters for each node describe the segments, the plurality of unit cells for that node, the plurality of photonic structures for that node, or both. As noted above, the structural parameters may include number, size, and shape of segments on the waveguide; number, size, and shape of unit cells within each segment; and number, size, shape, and pitch of photonic structures within each unit cell.

In some examples, the neural network comprises a graphical neural network. In this case, evaluating the at least one region comprises mapping the at least one region to a layer of the graphical neural network. As illustrated in FIG. 5B, for example, mapping the at least one region to the layer of the graphical neural network may be performed such that each segment of the at least one region corresponds to a node in the layer, and each node is connected to neighboring nodes by a plurality of edges. As also shown in FIG. 5B, each node may be embedded with information about the one or more structural parameters.

In some examples, the at least one prediction in step 608 comprises predicted ray tracing outputs for the at least one region of the selected waveguide (see steps 408 and 412 in FIG. 4). In this case, step 608 may include determining that accuracy of the predicted ray tracing outputs is sufficient, and determining one or more predicted performance parameters of the selected waveguide based on the predicted ray tracing outputs. Here, determining the one or more predicted performance parameters comprises using the predicted ray tracing outputs. In some examples, step 608 includes determining that accuracy of the predicted ray tracing outputs is insufficient, running a ray tracing algorithm for the at least one region of the selected waveguide (see step 416), and determining one or more predicted performance parameters of the selected waveguide based on output of the ray tracing algorithm.

In some examples, the at least one prediction in step 608 comprises one or more predicted performance parameters for the selected waveguide design. The one or more predicted performance parameters for a waveguide used for AR/MR display may comprise image quality, optical efficiency, field of view uniformity, color uniformity, resolution, eyebox uniformity, or any combination thereof.

As in method 400, the method 600 may include iteratively performing the selecting and evaluating steps 604 and 608 for other waveguide designs in the plurality of waveguide designs to yield a final waveguide design whose at least one prediction satisfies one or more criterion, such as criterion described with reference to steps 424 and 428. For example, step 608 implements a ranking/classification system that combines predicted performance parameters of all regions of the selected waveguide to optimize a single-objective loss function (e.g., by minimizing the objective loss function—meaning a difference between a prediction and a target for a particular performance parameter is lowest compared to other waveguides). If the objective loss function is considered minimized or near minimized for the selected waveguide design of that iteration, then the method 600 considers that selected waveguide design as the final waveguide design.

Although not explicitly illustrated, the method 600 may further comprise outputting an indication of the final waveguide design for fabrication in the same or similar manner as step 432.

FIG. 7 illustrates a schematic view of a head mounted display (HMD) 700 according to at least one example embodiment.

The HMD 700 may include a wearable frame 10 that supports elements of the HMD 700, hinges 11 at ends 10A of the frame 10 that enable movement of temple portions 12 that hold the HMD 700 to the head of an observer 40, ear pieces 13 that removably mount to ears of the observer 40, nose pads 14, wiring 15 that connects to an external processing circuit (not shown) where image processing operations are carried out, for example, on the basis of output from camera 18. The HMD 700 may further include headphones 16, headphone wirings 17, an image sensor or camera 18 mounted to a face 10B of the frame 10 in a central portion 10C of the frame 10, a member 20 to which image generating devices 111A and 111B are mounted through, for example, a casing 113, and waveguides 104 that rest in front of pupils 41 of the observer 40 when wearing the HMD 700. As may be appreciated, the image generating devices 111A and 111B may each include an optical system for providing input light to a respective waveguide 104. The optical system for each image generating device 111A and 111B may include one or more light sources, one or more lenses, one or more prisms or mirrors, one or more light modulators, and/or other suitable elements for generating input light for a waveguide 104. Each waveguide 104 take the form of one or more of the waveguides 104 discussed above with reference to FIGS. 1 to 12 and receive the input light shown in FIG. 1 from one of the image generating devices 111A and 111B. For example, one or more of the mechanisms from FIGS. 3A to 12D may be applied to form a waveguide 104.

Here, it should be appreciated that the above described details relate to one non-limiting example of an HMD 700, and the HMD 700 may include more or fewer elements than those illustrated and described above.

The embodiments described with reference to FIGS. 1-7 may be combined with one another in any suitable manner.

While this technology has been described in conjunction with a number of embodiments, it is evident that many alternatives, modifications and variations would be or are apparent to those of ordinary skill in the applicable arts. Accordingly, it is intended to embrace all such alternatives, modifications, equivalents, and variations that are within the spirit and scope of this disclosure.

It should be appreciated that inventive concepts cover any embodiment in combination with any one or more other embodiment, any one or more of the features disclosed herein, any one or more of the features as substantially disclosed herein, any one or more of the features as substantially disclosed herein in combination with any one or more other features as substantially disclosed herein, any one of the aspects/features/embodiments in combination with any one or more other aspects/features/embodiments, use of any one or more of the embodiments or features as disclosed herein. It is to be appreciated that any feature described herein can be claimed in combination with any other feature(s) as described herein, regardless of whether the features come from the same described embodiment.

Any processing devices, control units, processing units, etc. discussed above may correspond to one or many computer processing devices, such as a Field Programmable Gate Array (FPGA), an Application-Specific Integrated Circuit (ASIC), any other type of Integrated Circuit (IC) chip, a collection of IC chips, a microcontroller, a collection of microcontrollers, a microprocessor, Central Processing Unit (CPU), a digital signal processor (DSP) or plurality of microprocessors that are configured to execute the instructions sets stored in memory.

A computer readable signal medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device. Program code embodied on a computer readable signal medium may be transmitted using any appropriate medium, including but not limited to wireless, wireline, optical fiber cable, RF, etc., or any suitable combination of the foregoing.

The foregoing discussion has been presented for purposes of illustration and description. The foregoing is not intended to limit the disclosure to the form or forms disclosed herein. In the foregoing Detailed Description for example, various features of the disclosure are grouped together in one or more aspects, embodiments, and/or configurations for the purpose of streamlining the disclosure. The features of the aspects, embodiments, and/or configurations of the disclosure may be combined in alternate aspects, embodiments, and/or configurations other than those discussed above. This method of disclosure is not to be interpreted as reflecting an intention that the claims require more features than are expressly recited in each claim. Rather, as the following claims reflect, inventive aspects lie in less than all features of a single foregoing disclosed aspect, embodiment, and/or configuration. Thus, the following claims are hereby incorporated into this Detailed Description, with each claim standing on its own as an embodiment of the disclosure.

Moreover, though the description has included description of one or more aspects, embodiments, and/or configurations and certain variations and modifications, other variations, combinations, and modifications are within the scope of the disclosure, e.g., as may be within the skill and knowledge of those in the art, after understanding the present disclosure. It is intended to obtain rights which include alternative aspects, embodiments, and/or configurations to the extent permitted, including alternate, interchangeable and/or equivalent structures, functions, ranges or steps to those claimed, whether or not such alternate, interchangeable and/or equivalent structures, functions, ranges or steps are disclosed herein, and without intending to publicly dedicate any patentable subject matter.

It should be appreciated that inventive concepts cover any embodiment in combination with any one or more other embodiments, any one or more of the features disclosed herein, any one or more of the features as substantially disclosed herein, any one or more of the features as substantially disclosed herein in combination with any one or more other features as substantially disclosed herein, any one of the aspects/features/embodiments in combination with any one or more other aspects/features/embodiments, use of any one or more of the embodiments or features as disclosed herein. It is to be appreciated that any feature described herein can be claimed in combination with any other feature(s) as described herein, regardless of whether the features come from the same described embodiment.

As used herein, the phrases “at least one,” “one or more,” “or,” and “and/or” are open-ended expressions that are both conjunctive and disjunctive in operation. For example, each of the expressions “at least one of A, B and C,” “at least one of A, B, or C,” “one or more of A, B, and C,” “one or more of A, B, or C,” “A, B, and/or C,” and “A, B, or C” means A alone, B alone, C alone, A and B together, A and C together, B and C together, or A, B and C together.

Various aspects of the present disclosure are described herein with reference to drawings that may be schematic illustrations of idealized configurations.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and this disclosure.

As used herein, the singular forms “a,” “an,” and “the” are intended to include the plural forms as well, unless the context clearly indicates otherwise. It will be further understood that the terms “include,” “including,” “includes,” “comprise,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof. The term “and/or” includes any and all combinations of one or more of the associated listed items.

1. A device, comprising:
at least one processor; and
memory including instructions, that when executed by the at least one processor, cause the processor to:
select a waveguide design from among a plurality of waveguide designs, the selected waveguide design comprising at least one region having photonic structures; and
evaluate the at least one region of the selected waveguide design using a neural network, the neural network using one or more structural parameters of the at least one region as input to generate output that comprises at least one prediction for the selected waveguide design.

2. The device of claim 1, wherein the neural network comprises a graphical neural network.

3. The device of claim 2, wherein evaluating the at least one region comprises mapping the at least one region to a layer of the graphical neural network.

4. The device of claim 3, wherein the at least one region comprises a plurality of segments, each segment comprising a plurality of unit cells having the photonic structures.

5. The device of claim 4, wherein mapping the at least one region to the layer of the graphical neural network is performed such that:
each segment of the at least one region corresponds to a node in the layer; and
each node is connected to neighboring nodes by a plurality of edges.

6. The device of claim 5, wherein each node is embedded with information about the one or more structural parameters.

7. The device of claim 6, wherein the one or more structural parameters for each node describe the plurality of unit cells for that node, the plurality of photonic structures for that node, or both.

8. The device of claim 1, wherein selecting the selected waveguide design is based on output of a sampling algorithm applied to the plurality of waveguide designs.

9. The device of claim 1, wherein the at least one prediction comprises predicted ray tracing outputs for the at least one region of the selected waveguide.

10. The device of claim 9, wherein the memory includes instructions that when executed by the at least one processor, cause the at least one processor to:
determine that accuracy of the predicted ray tracing outputs is sufficient; and
determine one or more predicted performance parameters of the selected waveguide based on the predicted ray tracing outputs.

11. The device of claim 10, wherein evaluating the at least one region comprises:
combining the one or more predicted performance parameters of each of the at least one region of the selected waveguide to optimize a loss function.

12. The device of claim 9, wherein the memory includes instructions that when executed by the at least one processor, cause the at least one processor to:
determine that accuracy of the predicted ray tracing outputs is insufficient;
run a ray tracing algorithm for the at least one region of the selected waveguide; and
determine one or more predicted performance parameters of the selected waveguide based on output of the ray tracing algorithm.

13. The device of claim 1, wherein the at least one prediction comprises one or more predicted performance parameters for the selected waveguide design.

14. The device of claim 13, wherein the one or more predicted performance parameters comprise image quality, optical efficiency, field of view, color uniformity, resolution, or any combination thereof.

15. The device of claim 1, further comprising:
iteratively performing the selecting and evaluating steps for other waveguide designs in the plurality of waveguide designs to yield a final waveguide design whose at least one prediction satisfies one or more criterion; and
outputting an indication of the final waveguide design for fabrication.

16. The device of claim 1, wherein selecting the waveguide design is based on output of a machine learning algorithm.

17. A system, comprising:
at least one machine learning algorithm;
at least one processor; and
memory including instructions, that when executed by the at least one processor, cause the processor to:
select a waveguide design from among a plurality of waveguide designs, the selected waveguide design comprising at least one region having photonic structures; and
evaluate the at least one region of the selected waveguide design based on output of the neural network, the at least one machine learning algorithm using one or more structural parameters of the at least one region as input to generate output that comprises at least one prediction for the selected waveguide design.

18. The system of claim 17, wherein the at least one machine learning algorithm comprises a first machine learning algorithm and the at least one prediction comprises predicted ray tracing outputs for the at least one region of the selected waveguide output from the graphical neural network.

19. The system of claim 18, wherein the at least one machine learning algorithm comprises a second machine learning algorithm that uses output of the first machine learning algorithm to output the at least one prediction that comprises one or more predicted performance parameters for the selected waveguide design.

20. A method, comprising:
selecting a waveguide design from among a plurality of waveguide designs, the selected waveguide design comprising at least one region having photonic structures; and
evaluating the at least one region of the selected waveguide design using a graphical neural network, the neural graphical network using one or more structural parameters of the at least one region as input to generate output that comprises at least one prediction for the selected waveguide design.
